(19) United States
(12) Patent Application Publication
(10) Pub. No.: US 2012/0313190 A1
(43) Pub. Date: Dec. 13, 2012

(54) PACKAGED DEVICE INCLUDING INTERPOSER FOR INCREASED ADHESIVE THICKNESS AND METHOD OF ATTACHING DIE TO SUBSTRATE

(75) Inventors: Atul GOEL, Fort Collins, CO (US); Osvaldo BUCCAFUSCA, Fort Collins, CO (US)

(73) Assignee: Avago Technologies Wireless IP (Singapore) Pte. Ltd., Singapore (SG)

(21) Appl. No.: 13/156,509

(22) Filed: Jun. 9, 2011

(51) Int. Cl. H01L 29/84; H01L 29/02; H01L 21/50

(52) U.S. Cl. 257/416; 438/118; 257/782; 257/E21.499; 257/E29.324; 257/E29.002

(57) ABSTRACT

A device includes a die having: at least one of an electronic device and a microelectromechanical system, a package substrate, an electrically nonconductive interposer disposed between the die and the package substrate, at least a first adhesive layer disposed between the package substrate and the electrically nonconductive interposer, and at least a second adhesive layer disposed between the die and the electrically nonconductive interposer.

### BACKGROUND

In many applications, a semiconductor die may be attached to a package substrate with an adhesive layer to form a packaged device.

FIG. 1 shows a cross-section of a packaged device 10 including a package substrate 11, an adhesive layer 12, and a die 13.

In a die attachment process, the thickness of adhesive layer 12 is an important parameter for affecting the performance of packaged device 10. In most cases, adhesive layer 12 is expected to be thin to provide good thermal or electrical conductivity or good mechanical stability. Standard thicknesses for adhesive layer 12 may range from 10 um to about 50 um. This range of thicknesses is easily reproduced in a manufacturing environment by controlling the amount of adhesive that is dispensed, the geometry of the dispensed adhesive and the amount of pressure used in the die attachment process.

However, in certain special cases a thicker adhesive layer 12 is preferred. An example is in the case of packaging microelectromechanical systems (MEMS). A thicker adhesive layer 12 will better isolate die 13 from package substrate 11, reducing, for example, assembly induced stresses. In some cases, it is also desired to provide a thicker adhesive layer 12 as a cushion between package substrate 11 and die 13, for example to at least partially absorb vibrations to which package substrate 11 are exposed and isolate such vibrations from die 13. This might be the case, for example, when die 13 includes an acoustic resonator or transducer, such as piezoelectric MEMS ultrasonic transducer, which may comprise a microphone, pressure sensor, inertia sensor, etc.

When thicker adhesive layers are applied, technical problems such as adhesive bleeding, die tilting, and bond line variability make processes difficult to control. Alternative solutions for increased adhesive layer thickness include spacers such as beads. This solution has been proven in lab environments, but it did not find its way into commercial products due to the technical difficulties associated with variability control in mass production.

FIG. 2 a cross-section of a packaged device 20 including a package substrate 11, an adhesive layer 22, and a die 13.

The thickness B2 of adhesive layer 22 of packaged device 20 is substantially thicker than the thickness B1 adhesive layer 12 of packaged device 10, particularly in relation to the thickness A of package substrate 11 and the thickness C of die 13.

As can be seen in FIG. 2, when layer 12 becomes excessively thick, it is possible for die 13 to be tilted uncontrollably on adhesive layer 12. It is also possible for part of die 12 to settle or sink into adhesive layer 12 which may lead to bleeding of the adhesive material outside of the space between die 13 and package substrate 11, including for example onto the top surface of die 13 where it may damage or negatively affect the performance of die 13.

What is needed, therefore, is an arrangement where a die can be attached to a package substrate with a larger space or gap between the die and the package substrate in a controlled way that can avoid uncontrolled die tilting and adhesive bleeding, and a method of packaging a die that can provide a larger space or gap between the die and the package substrate and also avoid uncontrolled die tilting and adhesive bleeding.

### SUMMARY

In an example embodiment, a method of packaging a die comprises: providing a electrically nonconductive interposer, the electrically nonconductive interposer having substantially flat opposite first and second surfaces, wherein the first and second surfaces are in parallel with each other; attaching the electrically nonconductive interposer to a first surface of a package substrate with a first adhesive layer between the first surface of the package substrate and the first surface of the electrically nonconductive interposer; curing the first adhesive layer to bond the electrically nonconductive interposer to the package substrate; attaching a microelectromechanical systems (MEMS) die to the second surface of the electrically nonconductive interposer with a second adhesive layer between a back surface of the die and the second surface of the electrically nonconductive interposer; and curing the second adhesive layer to bond the MEMS die to the electrically nonconductive interposer.

In another example embodiment, a device comprises: a microelectromechanical systems (MEMS) die including at least one acoustic component; a package substrate having at least one aperture therethrough that is configured to communicate an acoustic wave between the at least one acoustic component and an exterior of the device; an electrically nonconductive interposer disposed between the MEMS die and the package substrate, wherein the electrically nonconductive interposer has at least one aperture therethrough that is configured to communicate the acoustic wave between the at least one acoustic component and the exterior of the device; at least a first adhesive layer disposed between the package substrate and the electrically nonconductive interposer; and at least a second adhesive layer disposed between the MEMS die and the electrically nonconductive interposer.

In yet another example embodiment, a device comprises: a die having at least one of an electronic device and a microelectromechanical system; a package substrate; an electrically nonconductive interposer disposed between the die and the package substrate; at least a first adhesive layer disposed between the package substrate and the electrically nonconductive interposer; and at least a second adhesive layer disposed between the die and the electrically nonconductive interposer.

### BRIEF DESCRIPTION OF THE DRAWINGS

The example embodiments are best understood from the following detailed description when read with the accompanying drawing figures. It is emphasized that the various features are not necessarily drawn to scale. In fact, the dimensions may be arbitrarily increased or decreased for clarity of discussion. Wherever applicable and practical, like reference numerals refer to like elements.

FIG. 1 shows a cross-section of a packaged device.

FIG. 2 shows a cross-section of a packaged device with a thick adhesive layer.

FIG. 3 shows a cross-section of one embodiment of a packaged device which includes an interposer.

FIG. 4 shows a cross-section of one embodiment of a packaged device which includes two interposers.

FIGS. 5A-B show plan views of two different embodiments of interposers.

FIG. 6 shows a cross-section of another embodiment of a packaged device which includes an interposer.

FIG. 7 shows a cross-section of yet another embodiment of a packaged device which includes an interposer.

FIG. 8 shows a cross-section of still another embodiment of a packaged device which includes an interposer.

### DETAILED DESCRIPTION

In the following detailed description, for purposes of explanation and not limitation, example embodiments disclosing specific details are set forth in order to provide a thorough understanding of an embodiment according to the present teachings. However, it will be apparent to one having ordinary skill in the art having had the benefit of the present disclosure that other embodiments according to the present teachings that depart from the specific details disclosed herein remain within the scope of the appended claims. Moreover, descriptions of well-known apparati and methods may be omitted so as to not obscure the description of the example embodiments. Such methods and apparati are clearly within the scope of the present teachings.

It is to be understood that the terminology used herein is for purposes of describing particular embodiments only, and is not intended to be limiting. The defined terms are in addition to the technical and scientific meanings of the defined terms as commonly understood and accepted in the technical field of the present teachings.

As used in the specification and appended claims, the terms ‘a’, ‘an’ and ‘the’ include both singular and plural referents, unless the context clearly dictates otherwise. Thus, for example, ‘a device’ includes one device and plural devices.

As used in the specification and appended claims, and in addition to their ordinary meanings, the terms ‘substantial’ or ‘substantially’ mean to within acceptable limits or degree.

As used in the specification and the appended claims and in addition to its ordinary meaning, the term ‘approximately’ means to within an acceptable limit or amount to one having ordinary skill in the art. For example, ‘approximately the same’ means that one of ordinary skill in the art would consider the items being compared to be the same

Generally, it is understood that the drawings and the various elements depicted therein are not drawn to scale. Further, relative terms, such as “above,” “below,” “top,” “bottom,” “upper” and “lower” may be used to describe the various elements' relationships to one another, as illustrated in the accompanying drawings. It is understood that these relative terms are intended to encompass different orientations of the device and/or elements in addition to the orientation depicted in the drawings. For example, if the device were inverted with respect to the view in the drawings, an element described as “above” another element, for example, would now be below that element.

The disclosures of these patents and patent applications are specifically incorporated herein by reference. It is emphasized that the components, materials and method of fabrication described in these patents and patent applications are representative and other methods of fabrication and materials within the purview of one of ordinary skill in the art are contemplated.

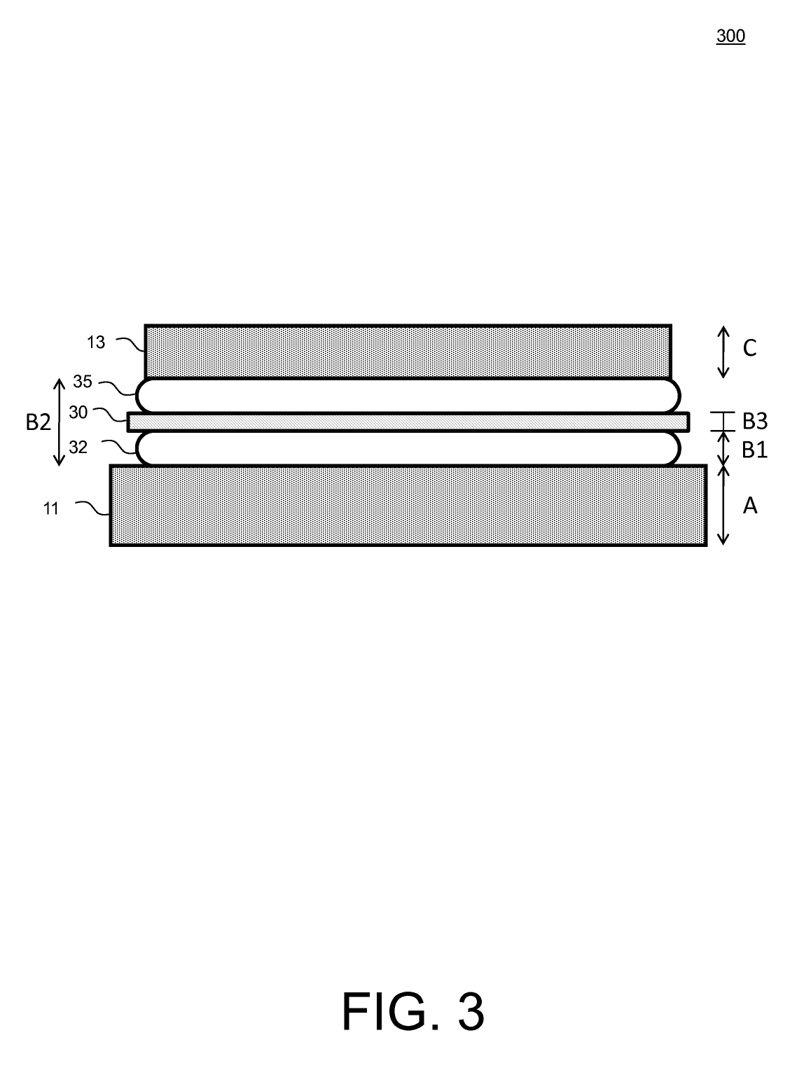

FIG. 3 shows a cross-section of one embodiment of a packaged device 300 which includes an interposer. Packaged device 300 includes a package substrate 11, a first adhesive layer 32, an interposer 30, a second adhesive layer 35, and a die 13.

In some embodiments, die 13 may be a semiconductor die having one or more electronic devices or components.

In some embodiments, die 13 may be a microelectromechanical systems (MEMS) die having one or more MEMS device.

In some embodiments, die 13 may include an acoustic component, such as an acoustic resonator or acoustic transducer. In some embodiments, die 13 may include a piezoelectric MEMS ultrasonic transducer, which may comprise a microphone, pressure sensor, inertia sensor, etc.

Significantly, interposer 30 is a thin (e.g., on the order of 20-500 μm thick), electrically nonconductive, structure that provides mechanical stability and both thermal and electrical isolation between package substrate 11 and die 13. Therefore, interposer 30 should not consist of a thermally and electrically conductive material such as copper, aluminum, zinc, or other metal, that may deform easily in thin plate form and can introduce undesirable localized stresses. Some examples of good materials for interposer 30 are ceramics, alumina, glass (e.g., silicate glass), silicon, Gallium Arsenide (GaAs), plastics, etc.

Interposer 30 has a first surface (bottom surface in FIG. 3) that is bonded to a first surface of package substrate 11 by first adhesive layer 32, and has a second surface (top surface in FIG. 3) that is bonded to a first (e.g., back) surface of die 13 by second adhesive layer 35. Beneficially, these first and second surfaces are substantially flat. In some embodiments, including the embodiment shown in FIG. 3, these first and second surfaces of interposer 30 are in parallel with each other.

Example adhesive materials for first and second adhesive layers 32 and 35 include epoxies, cyanoacrylates, or elastometers with suitable compliance and density characteristics. Specific examples of suitable adhesive materials are HYSOL® QMI 547 and ABLEBOND® MC723.

Package substrate 11 is part of a device package for at least partially encapsulating die 13. In some embodiments, package substrate is configured to be attached to a package cap (not shown in FIG. 3) for partially or totally enclosing die 13 therein. In some embodiments, package substrate 13 is configured to be attached to a lead frame (not shown in FIG. 3) for communicating electrical signals, including for example electrical power, to and/or from die 13. In that case, packaged device 300 may include one or more bond wires (not shown in FIG. 3) for electrically connecting one or more bonding pads (not shown in FIG. 3) of die 13 to the lead frame.

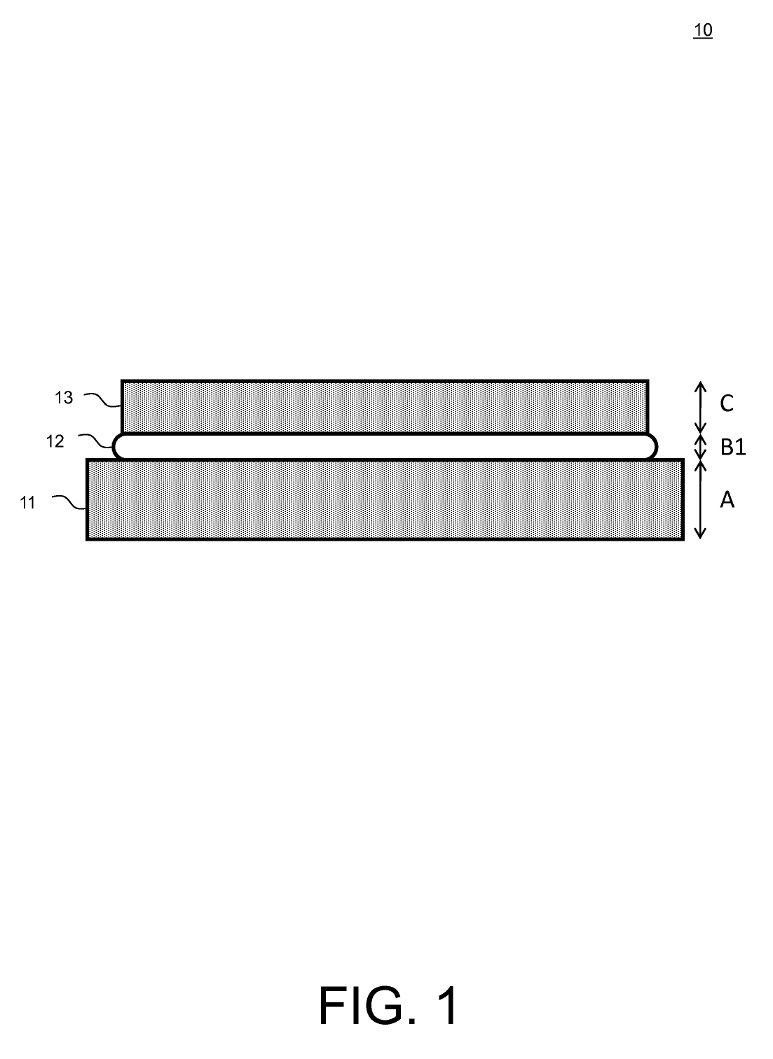

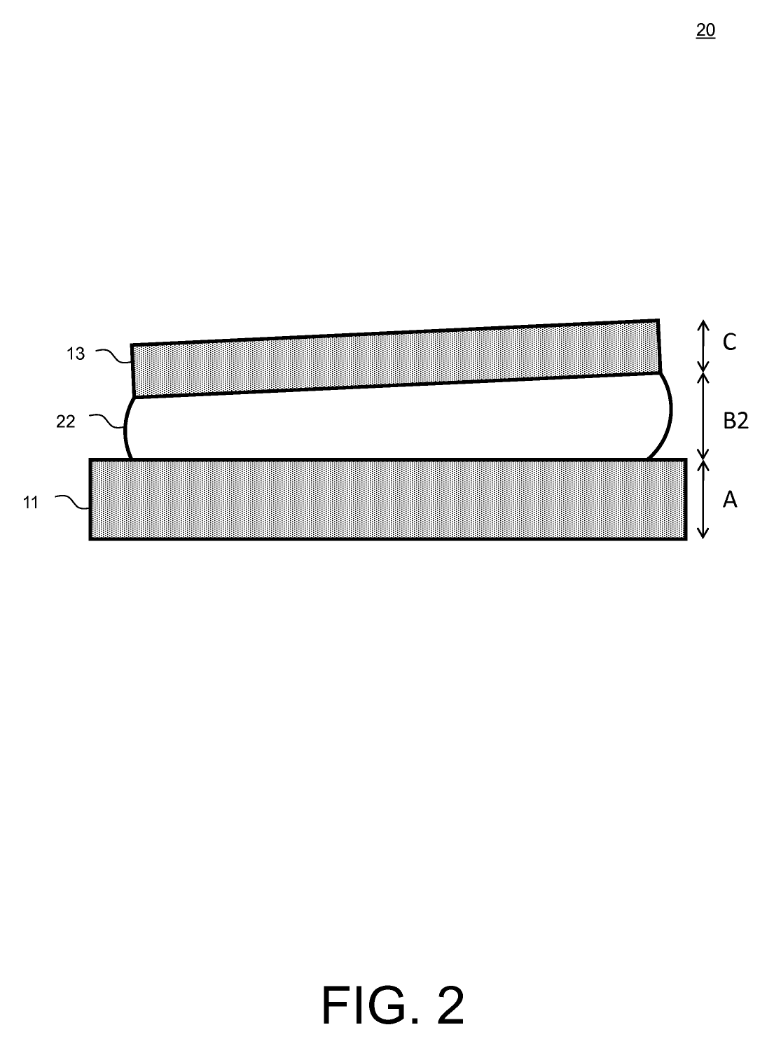

In the example embodiment shown in FIG. 2, first adhesive layer 32 has a thickness B1 which is the same as the example packaged device 10 illustrated in FIG. 1. However, the total thickness of the composite structure of first adhesive layer 32, interposer 30, and second adhesive layer 35 is B2, which is the same as the adhesive thickness in the example packaged device 20 illustrated in FIG. 2. However, whereas the die 13 was uncontrollably tilted on adhesive later 22 in the example packaged device 20 illustrated in FIG. 2, in packaged device 300 die 13 remains substantially untilted with respect to package substrate 11 be virtue of the mechanical integrity provided by interposer 30, and the use of two adhesive layers 32 and 35 which each may have a thickness that is substantially less than (e.g., less than one half the value of) the thickness B2 of adhesive layer 22 in device 20.

One method of manufacturing packaged device 300 is as follows. Interposer 30 is attached to a first surface of package substrate 11 with first adhesive layer 32 between the first surface of package substrate 11 and the first surface of interposer 30. Attaching interposer to the first surface of package substrate 11 may comprise applying a first adhesive material to areas on the interposer 30 and/or the first surface of package substrate 11 that correspond to corners of interposer 30. First adhesive layer is cured to bond interposer 30 to package substrate 11. Also, die 13 is attached to the second surface of the interposer 30 with second adhesive layer 35 between a back surface of die 13 and the second surface of interposer 30. Second adhesive layer 35 is cured to bond die 13 to interposer 30.

The other of the bonding steps may be performed with bonding interposer 30 to package substrate 11 first and then bonding interposer 30 to die 13, or with bonding die 13 to interposer 30 first and then bonding interposer 30 to package substrate 11.

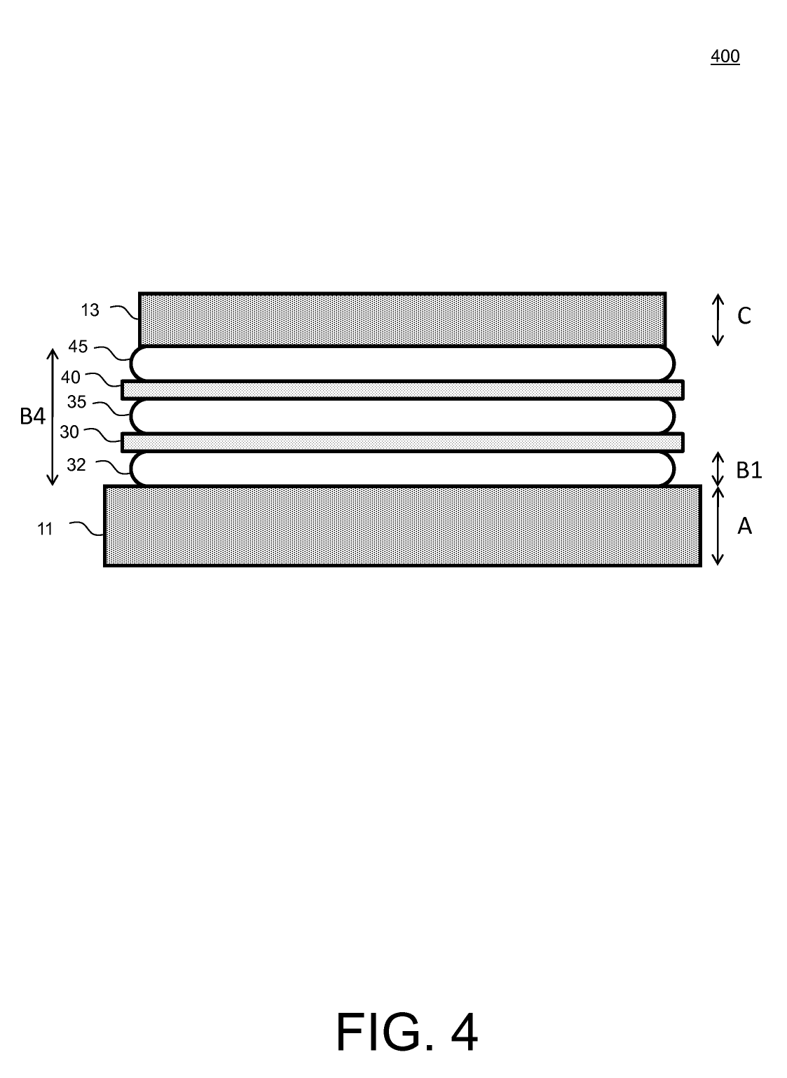

FIG. 4 shows a cross-section of one embodiment of a packaged device 400 which includes two interposers. Packaged device 400 includes a package substrate 11, a first adhesive layer 32, a first interposer 30, a second adhesive layer 35, a second interposer 40, a third adhesive layer 45, and a die 13.

The materials, structures, and characteristics of package substrate 11, a first adhesive layer 32, first interposer 30, second adhesive layer 35, and die 13 may be the same as described above with respect to FIG. 3, and therefore will not be repeated. Furthermore, second interposer 40 may have the same material, structure, and characteristics as first interposer 30, and third adhesive layer 45 may have the same material, structure, and characteristics as first and second adhesive layers 32 and 35.

Device 400 may be manufactured in stages, for example by bonding first interposer 30 to package substrate 11, then bonding first interposer 30 to second interposer 40, and then bonding second interposer 40 to die 30. These stages may be performed in a different order, for example by bonding first and second interposers 30 and 40 together first, and then bonding the resultant structure to package substrate 11 and die 13.

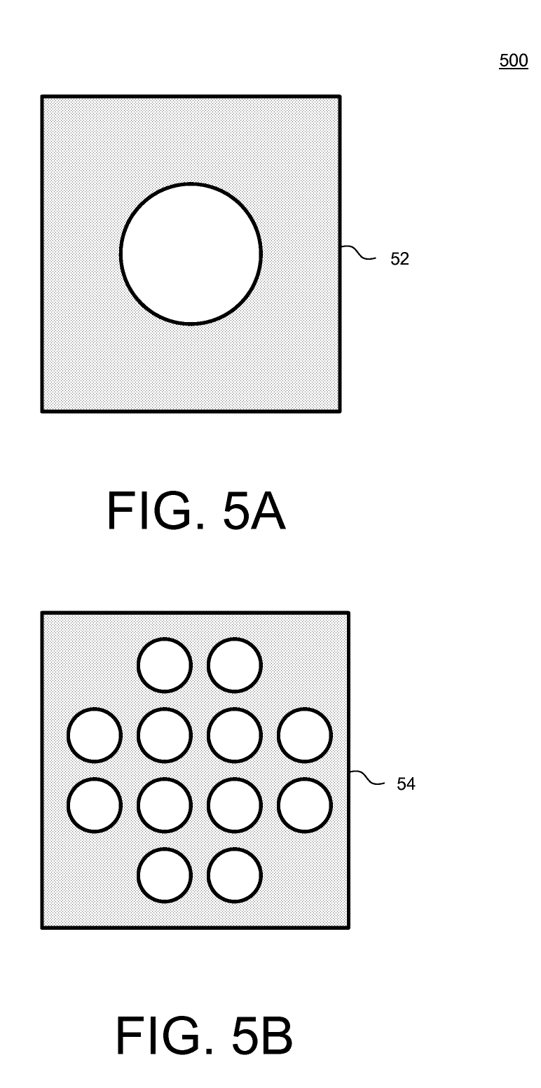

FIGS. 5A-B show plan views of two different embodiments of interposers 52 and 54. Interposer 52 has an aperture therethrough, and interposer 54 has a plurality of apertures therethrough. Interposers with one or more apertures therethrough may be employed, for example, when a die to be attached to a package includes an acoustic component such as an acoustic resonator or acoustic transducer. In that case, the aperture(s) may allow an acoustic wave generated by the acoustic component to be communicated to the outside of the packaged device and/or may allow an acoustic wave generated outside of the packaged device to be received by the acoustic component.

Other than the aperture(s) interposers 52 and 54 may have the same material, structure, and characteristics as interposer 30 discussed above with respect to FIG. 3. In particular, interposers 52 and 54 each comprise a thin, electrically nonconductive, structure that can provide mechanical stability and both thermal and electrical isolation between a package substrate and a die when employed in a packaged device. Therefore, interposers 52 and 54 should not consist of a thermally and electrically conductive material such as copper, aluminum, zinc, or other metal.

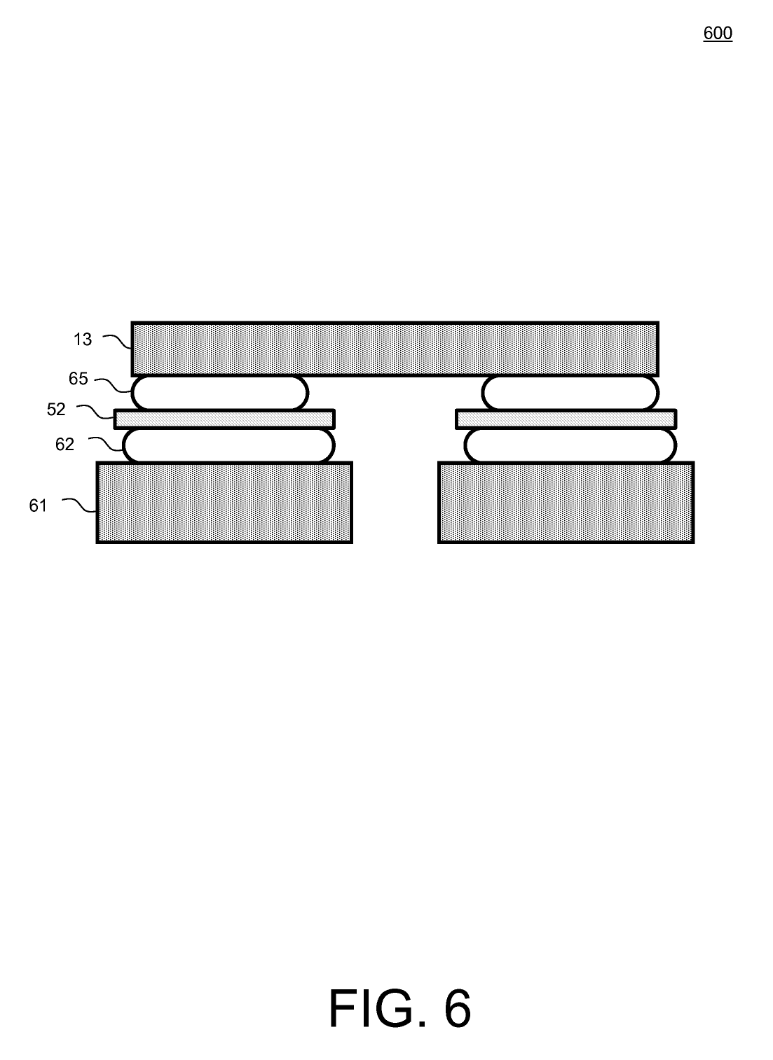

FIG. 6 shows a cross-section of another embodiment of a packaged device 600 which includes an interposer. In particular, packaged device 600 employs interposer 52 of FIG. 5A having an aperture therethrough. Packaged device 600 includes a package substrate 61, a first adhesive layer 62, interposer 52, a second adhesive layer 65, and a die 13.

The materials, structures, and characteristics of die 13 and interposer 52 may be the same as described above with respect to FIGS. 3 and 5A, and therefore will not be repeated. Furthermore, first and second adhesive layers 62 and 65 may have the same material, structure, and characteristics as first and second adhesive layers 32 and 35 described above, with a difference being that adhesive layers 62 and 65 are only at areas outside of the aperture of interposer 52, for example at corners of interposer 52. Also, package substrate 61 may have the same material, structure, and characteristics as package substrate 11 described above, with a difference being that package substrate 61 has an aperture therethrough that is generally aligned with the aperture in interposer 52.

In some embodiments, die 13 may include an acoustic component such as an acoustic resonator or acoustic transducer. In that case, the aperture(s) in interposer 52 and package substrate 61 may allow an acoustic wave generated by the acoustic component to be communicated to the outside of packaged device 600 and/or may allow an acoustic wave generated outside of packaged device 600 to be received by the acoustic component.

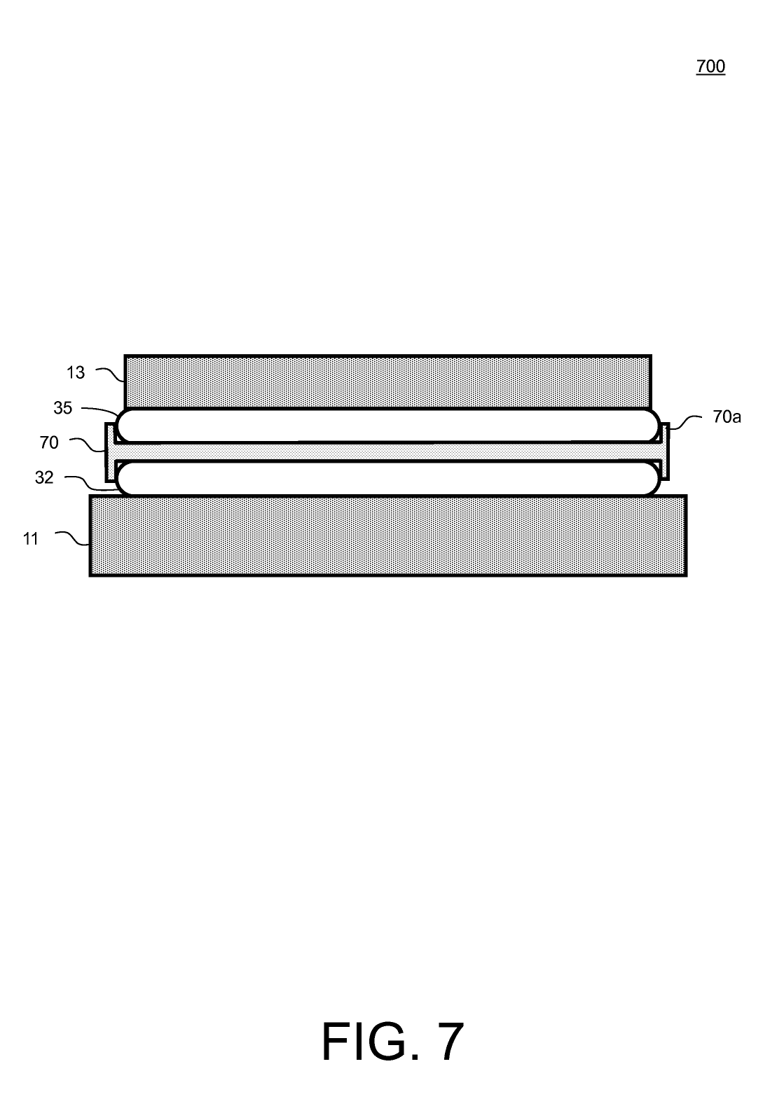

FIG. 7 shows a cross-section of yet another embodiment of a packaged device 700 which includes an interposer. Packaged device 700 includes package substrate 11, first adhesive layer 32, an interposer 70, second adhesive layer 35, and die 13. Packaged device 700 is the same as packaged device 300 described above, except for interposer 70 being different from interposer 30. Interposer 70 includes raised edges or lips 70a. Lips 70a may provide some measure of flow control for an adhesive material applied to interposer 70 when it is bonded to package substrate 11 and/or die 13. Otherwise, interposer 70 may be the same as interposer 30 described above.

Interposers 30, 40, 52, 54 and/or 70 may include other features not shown in the drawings, for example roughened surfaces or other features to improve adhesion.

In most cases, it will be highly desirable, or even critical, to employ an interposer where the opposite first and second surfaces are in parallel with each other so that the die and the package substrate will also be substantially in parallel with each other. However, it may be desirable in some embodiments to provide a controlled tilt angle between the die and the package substrate.

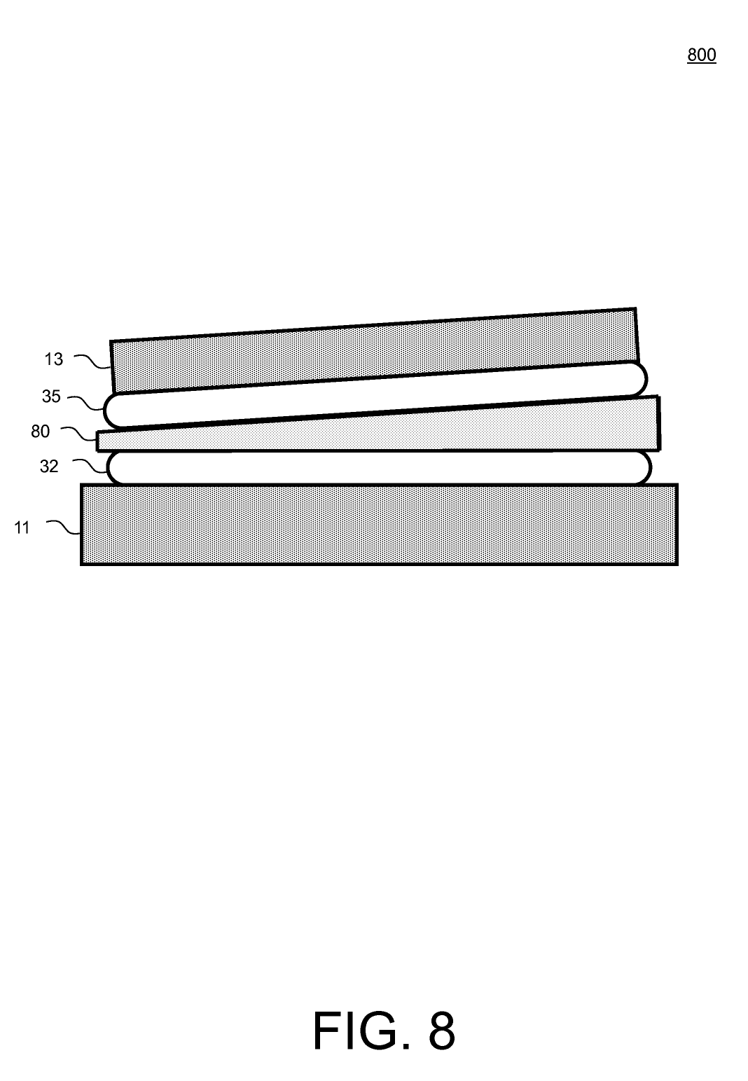

Toward this end, FIG. 8 shows a cross-section of still another embodiment of a packaged device 800 which includes an interposer. Packaged device 800 includes package substrate 11, first adhesive layer 32, an interposer 80, second adhesive layer 35, and die 13. Packaged device 800 is the same as packaged device 300 described above, except for interposer 80. Interposer 80 has the shape of a wedge. In particular, interposer 80 has substantially flat opposite first and second surfaces, wherein the first and second surfaces lie in respective planes that intersect each other with a predetermined, controlled angle therebetween such that when assembled in packaged device 800, die 13 is tilted by the same angle with respect to package substrate 11.

While example embodiments are disclosed herein, one of ordinary skill in the art appreciates that many variations that are in accordance with the present teachings are possible and remain within the scope of the appended claims. For example, packaged devices similar to those described above may employ interposers which combine any two or more of the various features shown in FIGS. 5A-B, 7 and 8 (e.g., include an aperture and a lip; have a wedge shape and include a plurality of apertures; etc.). The embodiments therefore are not to be restricted except within the scope of the appended claims.

1. A method, comprising:
providing a electrically nonconductive interposer, the electrically nonconductive interposer having substantially flat opposite first and second surfaces, wherein the first and second surfaces are in parallel with each other;
attaching the electrically nonconductive interposer to a first surface of a package substrate with a first adhesive layer between the first surface of the package substrate and the first surface of the electrically nonconductive interposer;
curing the first adhesive layer to bond the electrically nonconductive interposer to the package substrate;
attaching a microelectromechanical systems (MEMS) die to the second surface of the electrically nonconductive interposer with a second adhesive layer between a back surface of the die and the second surface of the electrically nonconductive interposer; and
curing the second adhesive layer to bond the MEMS die to the electrically nonconductive interposer.

2. The method of claim 1, wherein the electrically nonconductive interposer is an alumina substrate.

3. The method of claim 1, wherein the electrically nonconductive interposer is one of a glass substrate and a silicon substrate.

4. The method of claim 1, wherein attaching the electrically nonconductive interposer to the first surface of the package substrate comprises applying a first adhesive material to areas on at least one of: (1) the electrically nonconductive interposer, and (2) the first surface of the package substrate, that correspond to corners of the electrically nonconductive interposer.

5. A device, comprising:
a microelectromechanical systems (MEMS) die including at least one acoustic component;
a package substrate having at least one aperture therethrough that is configured to communicate an acoustic wave between the at least one acoustic component and an exterior of the device;
an electrically nonconductive interposer disposed between the MEMS die and the package substrate, wherein the electrically nonconductive interposer has at least one aperture therethrough that is configured to communicate the acoustic wave between the at least one acoustic component and the exterior of the device;
at least a first adhesive layer disposed between the package substrate and the electrically nonconductive interposer; and
at least a second adhesive layer disposed between the MEMS die and the electrically nonconductive interposer.

6. The device of claim 5, the electrically nonconductive interposers comprises an alumina substrate.

7. The device of claim 5, wherein the electrically nonconductive interposer comprises at least one of a glass substrate and a silicon substrate.

8. The device of claim 5, wherein the electrically nonconductive interposer is a first electrically nonconductive interposer, the device further comprising:
a second electrically nonconductive interposer having at least one aperture therethrough that is configured to communicate the acoustic wave between the at least one acoustic component and the exterior of the device; and
a third adhesive layer disposed between the first electrically nonconductive interposer and the second electrically nonconductive interposer,
wherein the first adhesive layer bonds the electrically nonconductive interposer to the package substrate, and
wherein the second adhesive layer bonds the electrically nonconductive interposer to the MEMS die.

9. The device of claim 5, wherein the electrically nonconductive interposer has substantially flat opposite first and second surfaces, wherein the first and second surfaces are in parallel with each other, and wherein the first adhesive layer bonds the first surface of the electrically nonconductive interposer and the package substrate.

10. The device of claim 9, wherein the second adhesive layer bonds the second surface of the electrically nonconductive interposer and the MEMS die.

11. The device of claim 9, wherein each of the first and second surfaces of the electrically nonconductive interposer has a lip along an edge thereof.

12. The device of claim 5, wherein at least one of the first adhesive layer and the second adhesive layer comprises one of an epoxy, a cyanoacrylate, and an elastometer.

13. The device of claim 5, wherein the electrically nonconductive interposer has a plurality of apertures therethrough that are configured to communicate the acoustic wave between the at least one acoustic component and the exterior of the device.

14. The device of claim 5, wherein the electrically nonconductive interposer has substantially flat opposite first and second surfaces, wherein the first and second surfaces lie in respective planes that intersect each other with an angle therebetween such that the MEMS die is tilted by the angle with respect to the package substrate.

15. A device, comprising:
a die having at least one of an electronic device and a microelectromechanical system;
a package substrate;
an electrically nonconductive interposer disposed between the die and the package substrate;
at least a first adhesive layer disposed between the package substrate and the electrically nonconductive interposer; and
at least a second adhesive layer disposed between the die and the electrically nonconductive interposer.

16. The device of claim 15, the electrically nonconductive interposers comprises an alumina substrate.

17. The device of claim 15, wherein the electrically nonconductive interposer comprises at least one of a glass substrate and a silicon substrate.

18. The device of claim 15, wherein the electrically nonconductive interposer is a first electrically nonconductive interposer, the device further comprising:
a second electrically nonconductive interposer; and
a third adhesive layer disposed between the first electrically nonconductive interposer and the second electrically nonconductive interposer,
wherein the first adhesive layer bonds the electrically nonconductive interposer to the package substrate, and
wherein the second adhesive layer bonds the electrically nonconductive interposer to the die.

19. The device of claim 15, wherein the electrically nonconductive interposer has substantially flat opposite first and second surfaces, wherein the first and second surfaces are in parallel with each other, and wherein the first adhesive layer bonds the first surface of the electrically nonconductive interposer and the package substrate.

20. The device of claim 15, wherein the electrically nonconductive interposer has substantially flat opposite first and second surfaces, wherein the first and second surfaces lie in respective planes that intersect each other with an angle therebetween such that the MEMS die is tilted by the angle with respect to the package substrate.
